(19) United States
(12) Patent Application Publication
(10) Pub. No.: US 2009/0229976 A1
(43) Pub. Date: Sep. 17, 2009

(54) Sputtering Target Material Containing Cobalt/Chromium/Platinum Matrix Phase and Oxide Phase, and Process for Producing the Same

(75) Inventors: Kazuteru KATO, Omuta-shi (JP); Junichi KIYOTO, Ushiku-shi (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining & Smelting Co., Ltd., Tokyo (JP)

(21) Appl. No.: 12/401,280

(22) Filed: Mar. 10, 2009

(30) Foreign Application Priority Data
Mar. 11, 2008 (JP) 2008-061310

(51) Int. Cl. C23C 14/10; C23C 14/08; B22F 1/00; B22F 3/105

(52) U.S. Cl. 204/298.13; 419/19; 419/20

(57) ABSTRACT

Sputtering target materials have improved film-sputtering properties by containing finer metal oxide particles. A process for producing a sputtering target material including a cobalt/chromium/platinum matrix phase and an oxide phase that includes two or more metal oxides including at least chromium oxide wherein the oxide phase is in the form of particles, includes sintering material powder to form the sputtering target material wherein the material powder contains chromium oxide at not less than 1.0 mol % based on the material powder.

### FIELD OF THE INVENTION

The present invention relates to sputtering target materials comprising a cobalt/chromium/platinum matrix phase and an oxide phase wherein the oxide phase comprises two or more metal oxides, and to processes for producing the target materials. In more detail, the invention relates to processes for producing sputtering target materials in which chromium oxide powder is used in an amount such that the content of chromium oxide in material powder is at least 1.0 mol %, whereby sputtering target materials particularly suited to sputter magnetic recording films are obtained; and to sputtering target materials obtained by the processes.

### BACKGROUND OF THE INVENTION

Hard disk devices used as external recording devices require high-density recording capacity to be compatible with high-performance computers and digital appliances. Perpendicular magnetic recording technology enabling high-density recording performance has attracted attention. Perpendicular magnetic films used in this technology are frequently Co-containing alloy magnetic films. In the magnetic films, as known in the art, the media noise is reduced and the storage density is increased by forming phases in the films from fine crystal particles and controlling the size distribution of the crystal particles thereby to decrease the magnetic interaction among the particles.

The Co-containing alloy magnetic films are currently obtained by sputtering a sputtering target. For improvements in storage density and coercive force of the magnetic films, various researches and developments are underway to enhance the quality of sputtering targets.

For example, Patent Document 1 discloses a sputtering target material including a Co-containing alloy and describes that films of high coercive force may be formed therefrom. However, the production of the sputtering target materials entails sintering at certain levels of high temperatures and high pressures. Accordingly, improvements are still required in productivity of the sputtering target materials.

Patent Document 2 discloses a high-density sputtering target material that includes a Co-containing magnetic metal phase and a non-magnetic metal oxide phase. The metal oxide phase is described to be formed of a single metal oxide or a mixture of metal oxides sintered to each other. However, the metal oxides forming the non-magnetic phase are limited to metal oxides having a fairly low melting point, whilst the manufacturing of the sputtering target materials involves sintering at high temperatures and high pressures. It is probable that the low-melting point metal oxides are grown into coarse particles by the sintering.

Patent Document 3 discloses a sputtering target containing 2 to 15% by mass of silica, 0.01 to 0.5% by mass of chromium oxide, 3 to 20% by mass of Cr, 15 to 45% by mass of Pt and the remaining percentage of Cr. The target is aimed at reducing the scattering of particles. According to this patent document, however, the amount of chromium oxide is limited to a very low level and it is described that any chromium oxide content in excess of the above amounts leads to heavy scattering of particles. Further, the particles of the metal oxides in this sputtering target are not sufficiently fine.
Patent Document 1: JP-A-2007-154248
Patent Document 2: JP-A-2006-348366
Patent Document 3: JP-A-2007-31808

### SUMMARY OF THE INVENTION

It is therefore an object of the present invention to provide sputtering target materials that have improved film-sputtering properties by containing finer oxide-phase particles, and to provide processes for producing such sputtering target materials.

A process for producing a sputtering target material comprising a cobalt/chromium/platinum matrix phase and an oxide phase that comprises two or more metal oxides including at least chromium oxide wherein the oxide phase is in the form of particles, which process comprises sintering material powder to form the sputtering target material wherein the material powder contains chromium oxide at not less than 1.0 mol % based on the material powder.

The particles forming the oxide phase preferably have an average particle diameter of not more than 3 μm.

The oxide phase preferably comprises chromium oxide and at least one metal oxide selected from the group consisting of silicon oxide, titanium oxide, tantalum oxide, aluminum oxide, magnesium oxide, calcium oxide, zirconium oxide, boron oxide, manganese oxide, samarium oxide, hafnium oxide and gadolinium oxide.

A sputtering target material according to the present invention comprises a cobalt/chromium/platinum matrix phase and an oxide phase that comprises two or more metal oxides including at least chromium oxide wherein the oxide phase is in the form of particles having an average particle diameter of not more than 3 μm and comprises chromium oxide and a Si-containing oxide, the sputtering target material containing chromium oxide at 1.2 to 12.0 mol % and the Si-containing oxide at 1.5 to 11.9 mol % based on the sputtering target material.

### ADVANTAGES OF THE INVENTION

According to the production processes of the present invention, chromium oxide is used at the specific amount and thereby sputtering target materials may be obtained in which the oxide phase is formed of finer particles. According to the production processes, sintering can be completed at relatively low temperatures and therefore sputtering target materials may be produced more efficiently.

The sputtering target materials of the present invention are obtained by the above processes and have a high density as a result of sufficiently suppressing the growth of crystal particles according to the production process, thereby reducing the occurrence of particle scattering and arcing. Further, the sputtering target materials have low magnetic permeability and are capable of increased sputtering speed to enable high-speed sputtering.

### PREFERRED EMBODIMENTS OF THE INVENTION

The present invention will be described in detail hereinbelow.

In the present invention, the words “oxide phase” refer to a phase formed of two or more metal oxides including at least chromium oxide. In detail, the oxide phase is a mixture of metal oxides including chromium oxide and one or more other metal oxides such as SiO₂, Al₂O₃ and Y₂O₃. The term “matrix phase” refers to a phase other than the oxide phase. In detail, the matrix phase is formed of metals including cobalt, chromium and platinum and does not contain the above metal oxides.

### <Processes for Producing Sputtering Target Materials>

By the processes of the present invention, there may be obtained sputtering target materials containing a cobalt/chromium/platinum matrix phase and an oxide phase that is formed of two or more metal oxides including at least chromium oxide wherein the oxide phase is in the form of particles. In the processes, a sputtering target material is produced by sintering material powder which contains chromium oxide at not less than 1.0 mol % based on the material powder.

In the production of sputtering target materials, material powder which contains metals including cobalt, chromium and platinum and two or more metal oxides including at least chromium oxide is sintered. The material powder may be powder (B) obtained from powder (A) by the following method.

The powder (A) is obtained by mechanically alloying a Co/Cr alloy and metal oxides. First, the Co/Cr alloy may be atomized into powder. The alloy used herein usually has a Cr concentration of 5 to 95 atm %, and preferably 10 to 70 atm %.

The atomizing methods are not particularly limited and include water atomization, gas atomization, vacuum atomization and centrifugal atomization, with gas atomization being preferable. The outlet temperature is generally in the range of 1420 to 1800° C., and preferably 1420 to 1600° C. The gas atomization method generally involves injection of N₂ gas or Ar gas. Injection of Ar gas is preferable because oxidation is suppressed and spherical particles are atomized. Atomizing the above alloy gives atomized powder having an average particle diameter of 10 to 600 μm, preferably 10 to 200 μm, and more preferably 10 to 80 μm.

The Co/Cr alloy or atomized powder thereof is mechanically alloyed with metal oxides to afford powder (A). The metal oxides used herein are two or more metal oxides including at least chromium oxide, that is, the metal oxides are chromium oxide and one of more metal oxides other than chromium oxide.

Specific examples of chromium oxides include Cr₂O₃, CrO, CrO₂, Cr₂O₅ and CrO₃, with Cr₂O₃ being preferred. A single or two or more kinds of chromium oxides may be used. The usage amount of chromium oxide powder is generally such that the chromium oxide content is not less than 1.0 mol %, preferably in the range of 1.0 to 12.0 mol %, and more preferably 2.5 to 5.0 mol % based on the material powder, namely, based on a powder mixture obtained by mixing all the component powders. The chromium oxide powder desirably has an average particle diameter of not more than 3 μm, and preferably not more than 2.5 μm. By controlling the usage amount and particle diameter of the chromium oxide powder in the above ranges, the chromium oxide content in the sputtering target material is generally not less than 1.2 mol %, preferably in the range of 1.2 to 12.0 mol %, and more preferably 2.6 to 5.1 mol %. Further, the above usage amount and particle diameter ensure that chromium oxide and other metal oxides as will be described later can form fine oxide-phase particles having an average particle diameter of not more than 3 μm, preferably in the range of 2.0 to 3.0 μm, and more preferably 2.0 to 2.5 μm.

In the specification, the average particle diameter of chromium oxide powder is a D₅₀ value determined by a microtrack method. The average particle diameter of the oxide-phase particles may be determined as follows. A cross section of the sputtering target material is observed with a scanning electron microscope (SEM), and a diagonal line is drawn in a ×1000 SEM image. The maximum and minimum diameters of the oxide-phase particles that are found on the diagonal line are measured. The average of the maximum and minimum particle diameters is obtained as the average particle diameter.

The contents of the above components in the sputtering target material may be determined based on the composition of the sputtering target material. In the specification, the composition of the sputtering target material is determined while the chromium oxide content is obtained in terms of Cr₂O₃ that is a stable form of chromium oxide and the silicon atoms are regarded as existing as SiO₂. Cr and Cr₂O₃ may be discriminated from each other by Cr analysis and oxygen analysis of the sputtering target material.

Examples of the metal oxides other than the chromium oxides include oxides of metals such as Si, Ti, Ta, Al, Mg, Ca, Zr, B, Mn, Sm, Hf and Gd. Specific examples are SiO₂, TiO₂, Ta₂O₅, Al₂O₃, MgO, CaO, ZrO₂, B₂O₃, Sm₂O₃, HfO₂ and Gd₂O₃. Of these Si-containing oxides are preferred, and SiO₂ is more preferred. A single or a mixture of two or more kinds of these metal oxides may be used. The usage amount of the metal oxide powders other than the chromium oxide powder is generally such that the content thereof in the material powder is in the range of 1.5 to 12.0 mol %, preferably 1.5 to 2.5 mol %, and more preferably 1.5 to 2.0 mol %. By controlling the usage amount of the metal oxide powders other than the chromium oxide powder in the above range, the content of the metal oxides in the sputtering target material is generally in the range of 1.5 to 11.9 mol %, preferably 1.5 to 2.5 mol %, and more preferably 1.5 to 2.0 mol %. The above usage amount of the metal oxide powders other than the chromium oxide powder, in combination with the foregoing usage amount of the chromium oxide powder, provide an advantage that the obtainable oxide phase is formed of finer particles. The powder (A) may contain powders of other elements such as tantalum, niobium, copper and neodymium in addition to the chromium oxide powder and other metal oxide powders while still achieving the advantages of the present invention. The mechanical alloying is generally performed in a ball mill.

The grinding rate of the powder (A) is generally 30 to 95%, preferably 50 to 95%, and more preferably 80 to 90%. The powder (A) having this grinding rate is sufficiently fine, and the oxide phase in the target material is formed of finer particles and such fine oxide-phase particles are homogeneously dispersed in the matrix phase formed of cobalt, chromium and platinum. Furthermore, the above grinding rate ensures that the contamination with impurities such as zirconium or carbon that tends to increase with increasing grinding rate is appropriately suppressed.

The grinding rate refers to a value α (%) obtained from Equation (i) below:

Grinding rate α(%)={(D₉₀(0)−D₉₀(t))/D₉₀(0)}×100 (i)

wherein D₉₀(0) is a diameter D₉₀ determined by a microtrack method before the grinding and D₉₀(t) is a diameter D₉₀ measured after the particles are ground for a given time (t).

To achieve the above grinding rate, the particles may be ground using a ball mill. High-purity zirconia balls or alumina balls may be used, and high-purity zirconia balls are suitably used. The zirconia balls may generally range in diameter from 1 to 20 mm. Ball mills made of resins or resin ball mills in which a plate formed from constituent elements of the target material is attached to the resin may be used.

Instead of the powder (A) produced as described above, Cr-containing powder may be directly used in the subsequent steps. The Cr-containing powder contains Co and Cr and may contain other components such as metal oxides as long as it satisfies the content of chromium oxides as described above.

Next, the powder (A) and platinum powder are mixed together to give powder (B). The platinum powder is preferably element powder. The mixing methods are not particularly limited, but mixing with a blender mill is preferable.

Prior to the subsequent step of sintering, the particle size of the powder (B) may be regulated using, for example, an oscillating sieve. Regulating the particle size further increases the homogeneity of the powder (B).

By sintering the powder (B), the sputtering target material of the present invention may be obtained. The sintering temperature is generally not more than 1100° C., preferably in the range of 800 to 1100° C., and more preferably from above 950 to 1100° C. The sintering pressure is generally 10 to 100 MPa, preferably 20 to 80 MPa, and more preferably 30 to 60 MPa. The sintering is preferably carried out in an oxygen-free atmosphere, and particularly preferably in an argon atmosphere.

After the initiation of the sintering, the temperature is increased at 250 to 6000° C./h, and preferably 1000 to 6000° C. and the maximum sintering temperature is reached in 10 minutes to 4 hours.

The retention time for the maximum sintering temperature (sintering time) generally ranges from about 3 minutes to 5 hours. This sintering time ensures that the relative density of the target material is increased while the growth of the oxide-phase fine particles is effectively suppressed.

After the retention of the maximum sintering temperature, the temperature is generally lowered to 200-400° C. in 1 to 3 hours at a rate of 300 to 1000° C./h, preferably 500 to 1000° C./h, and more preferably 700 to 1000° C./h.

In the processes for producing sputtering target materials, it is preferred that the sintering temperature is in the above range, and it is more preferred that the sintering temperature is in the above range and the temperature is lowered at the above rate. That is, it is more desirable that the sintering is carried out at relatively low temperatures and the temperature is lowered rapidly after the sintering completes. According to this preferred embodiment, the oxide-phase particles are effectively prevented from growing and the quality of the obtainable target materials may be enhanced.

Suitable sintering temperature and retention time for the maximum sintering temperature are variable depending on the composition of the target material. For example, when the composition of the material powder consists of 66.5 mol % of Co, 19.0 mol % of Pt, 9.5 mol % of Cr, 2.5 mol % of SiO₂ and 2.5 mol % of Cr₂O₃, the sintering temperature is preferably about 800 to 1100° C. and the retention time for the maximum sintering temperature (sintering time) is preferably from 3 minutes to 5 hours.

Electric current sintering is a method in which sintering is performed by applying a high current under pressure and through the application of voltage. Spark plasma sintering, electric discharge sintering and plasma activated sintering are examples. This method utilizes a discharge phenomenon occurring between material particles, and sintering is induced by the activation of the particle surface by discharge plasma, the electromigration effects caused by electric fields, the thermodiffusion effects by the Joule heat, and the plastic deformation pressures by the application of pressure. The electric current sintering permits sufficiently sintering a molded article even at low temperatures such as the foregoing sintering temperature and is also advantageous in that the rapid temperature lowering is easily feasible.

When sintering is performed by the conventional hot pressing (HP) method at low temperatures, the growth of oxide-phase particles is prevented at some level; however, it tends to be difficult to obtain high-density sputtering target materials. In contrast, the electric current sintering has easy controlling of sintering temperature conditions, so that the oxide-phase particles are prevented from growing even when sintered at low temperatures and high-density sputtering target materials are easily manufactured. Accordingly, the electric current sintering is a suited sintering method for the production processes of the present invention.

### <Sputtering Target Materials>

The sputtering target materials of the present invention have a matrix phase including cobalt, chromium and platinum, and an oxide phase that comprises two or more metal oxides including at least chromium oxide. The oxide phase is in the form of particles having an average particle diameter of not more than 3 μm. The average particle diameter of the oxide-phase particles in the sputtering target materials is generally not more than 3 μm, preferably in the range of 2.0 to 3.0 μm, and more preferably 2.0 to 2.5 μm.

The oxide phase includes chromium oxide and a Si-containing oxide. The content of chromium oxide in the sputtering target material is usually not less than 1.2 mol %, preferably from 1.2 to 12.0 mol %, and more preferably from 2.6 to 5.1 mol %. The content of the Si-containing oxide in the sputtering target material is usually from 1.5 to 12.0 mol %, and preferably from 1.5 to 2.0 mol %.

The ratio on a molar basis between the Si-containing oxide content and the chromium oxide content ((mol % of Si-containing oxide):(mol % of chromium oxide)) is suitably 1.0:0.2 to 1.0:4.9. To make sure that the oxide-phase particles will have an average particle diameter of 2.0 to 2.5 μm, the molar ratio is preferably 1.0:1.1 to 1.0:2.1. The oxide phase may often contain trace amounts of oxides of cobalt, chromium or platinum formed in the air or during the sintering.

The respective contents of cobalt, chromium and platinum are not particularly limited. However, the cobalt content is usually 59.2 to 68.2 mol %, preferably 64.0 to 66.4 mol %, the chromium content is 9.3 to 10.6 mol %, preferably 10.1 to 10.5 mol %, and the platinum content is 16.9 to 19.5 mol %, preferably 18.3 to 19.0 mol % based on the sputtering target material.

Because of the oxide phase containing chromium oxide and Si-containing oxide in the above amounts, the particles forming the oxide phase achieve finer particle diameters. Such finer oxide-phase particles can be homogeneously dispersed in the sputtering target material, and the sputtering target materials achieve a high density as a result. Accordingly, the occurrence of particle scattering and arcing during the sputtering can be greatly reduced by using the sputtering target materials of the present invention.

The relative density of the sputtering target materials of the present invention is generally not less than 90%, preferably not less than 95%, and more preferably not less than 97%. This relative density is a value measured by the Archimedes' principle with respect to the sintered sputtering target materials. The upper limit is not particularly limited, but the relative density is generally not more than 100%. According to the Archimedes' principle, the weight in air of the sintered target material is divided by the volume (=sintered target material's weight in water/specific gravity of water at the measurement temperature), and the relative density is expressed in percentage (%) relative to the theoretical density ρ (g/cm³) represented by the following equation (X).

$$\begin{matrix}[ Formula 1 ] & \\ ρ ≡ {( \frac{{C}_{1} / 100}{{ρ}_{1}} + \frac{{C}_{2} / 100}{{ρ}_{2}} + … + \frac{{C}_{i} / 100}{{ρ}_{i}} )}^{- 1} & ( X )\end{matrix}$$

wherein C₁ to Cᵢ are each a content (wt %) of a component of the sintered target material, and ρ₁ to ρᵢ are each a density (g/cm³) of a component corresponding to C₁ to Cᵢ.

The increased dispersibility of the oxide-phase fine particles is probably responsible for the uniform lowering in magnetic permeability of the sputtering target materials, and the increased film-sputtering rate is achieved as a result.

### <Magnetic Recording Films>

The sputtering target materials of the invention are suitably used to sputter magnetic recording films, and particularly perpendicular magnetic films. The perpendicular magnetic films are recording films in which the easy axes of magnetization are mainly perpendicular to the non-magnetic substrate and thereby higher storage density is achieved. By sputtering the sputtering target material joined with a backing plate (i.e., sputtering target), magnetic recording films of high quality may be formed at high speed.

Suitable sputtering methods used in the film production include DC-magnetron sputtering and RF-magnetron sputtering. The film thickness is not particularly limited, but is usually from 5 to 100 nm, and preferably from 5 to 20 nm.

The magnetic recording films obtained from the sputtering targets will contain cobalt, chromium and platinum at approximately more than 95% of the desired concentrations. Further, because the sputtering target materials of the invention have finer oxide-phase particles, the magnetic recording films sputtered therefrom have high homogeneity and density. Furthermore, the magnetic recording films have high coercivity and excellent magnetic properties such as perpendicular magnetic anisotropy and perpendicular coercive force, and are therefore particularly suited as perpendicular magnetic films.

### EXAMPLES

The present invention will be described based on Examples hereinbelow without limiting the scope of the invention. Evaluations were carried out in the following procedures.

### <Relative Density>

The relative density was measured by the Archimedes' principle. In detail, the weight in air of the sintered sputtering target material was divided by the volume (=sintered target material's weight in water/specific gravity of water at the measurement temperature), and the relative density was expressed in percentage (%) relative to the theoretical density ρ (g/cm³) represented by the above-described equation (X).

### <Average Particle Diameter of Oxide-Phase Particles>

A cross section of the sputtering target material was observed with a scanning electron microscope (manufactured by JEOL DATUM), and a diagonal line was drawn in a 1200 μm×1600 μm SEM image (accelerating voltage: 20 kV). The maximum and minimum diameters of all the oxide-phase particles that were found on the diagonal line were measured. The average of the maximum and minimum particle diameters was obtained as the average particle diameter.

### <Composition of Sputtering Target Material>

The composition of the sputtering target material was determined while the chromium oxide content was obtained in terms of Cr₂O₃ that is a stable form of chromium oxide and the silicon atoms were regarded as existing as SiO₂. The oxygen analysis was performed using EMGA-500 (oxygen analysis device manufactured by HORIBA Ltd.) based on a calibration curve that had been prepared with silicon nitride powder (JCRM R005, The Ceramic Society of Japan, average oxygen concentration: 1.65±0.12 wt %) as a ceramic standard. The contents of Co, Cr, Pt and Si were determined with the use of an ICP emission spectrometer. From the results of the Cr analysis and oxygen analysis, Cr and Cr₂O₃ were discriminated from each other.

### Example 1

Co/Cr alloy weighing 2 kg was atomized into powder by injecting Ar gas thereto at 50 kg/cm² with the use of a micro gas atomizer (manufactured by NISSHIN-GIKEN Corporation) at an outlet temperature of 1650° C. (measured with a radiation thermometer). The powder obtained was spherical powder having an average particle diameter of not more than 150 μm.

The powder was mechanically alloyed with SiO₂ powder (average particle diameter: about 0.5 μm) in a ball mill.

The resulting powder was mechanically alloyed with Cr₂O₃ powder (average particle diameter: about 3 μm) in the same manner as above to give powder (A).

The powder (A) was mixed with Pt powder (average particle diameter: about 0.5 μm) and Co powder having an average particle diameter similar to that of the Pt powder in a ball mill so as to afford powder (B) having a composition Co₆₅Cr₁₂Pt₁₅(SiO₂)_{2.5}(Cr₂O₃)_{1.0}.

The particle size of the powder (B) was regulated using an oscillating sieve.

The powder (B) was placed in a mold and was sintered using an electric current sintering apparatus under the following conditions.

### [Sintering Conditions]

Sintering atmosphere: Ar

Temperature increasing rate: 800° C./h

Sintering temperature: 1050° C.

Retention time for maximum sintering temperature: 10 min

Pressure: 50 MPa

Temperature lowering rate: 400° C./h (from the maximum sintering temperature to 200° C.)

The sintered body was machined into a sputtering target having a diameter of 4 inch. The measurement results with the sintered body are shown in Table 1.

### Examples 2-7 and Comparative Examples 1-2

Powders (B) were obtained and sintered under the conditions set forth in Table 1 in the same manner as in Example 1 except that the amounts of SiO₂ and Cr₂O₃ were changed as shown in Table 1. The sintered bodies were machined into sputtering targets having a diameter of 4 inch. The measurement results with the sintered bodies are shown in Table 1.

### Reference Examples 1-2

Powders (B) were obtained in the same manner as in Example 1 except that the amounts of SiO₂ and Cr₂O₃ were changed as shown in Table 1. The powders were sintered using a hot press machine under the following conditions, and the sintered bodies were machined into sputtering targets having a diameter of 4 inch. The measurement results with the sintered bodies are shown in Table 1.

### [Sintering Conditions]

Sintering atmosphere: Ar

Temperature increasing rate: 450° C./h

Sintering temperature: 1150° C.

Retention time for maximum sintering temperature: 1 hour Pressure: 30 MPa

Temperature lowering rate: 150° C./h (from the maximum sintering temperature to 300° C.)

TABLE 1

| | | | | | | | | | | | | | | Average | |
|---|---|---|---|---|---|---|---|---|---|---|---|---|---|---|---|
| | | | | | | | | | | | | | | particle | |
| | | | | | | | | | | | | | | diameter | |
| | | | | | | Cr | | | | | | | | of oxide | |
| | Usage amount (mol %) in material | | | | | analysis | Composition of sputtering target | | | | | | Sintering | phase | Relative |
| | powder | | | | | result | material (mol %) | | | | | Cr₂O₃/SiO₂ | temperature | particles | density |
| | Co | Cr | Pt | SiO₂ | Cr₂O₃ | (wt %) | Co | Cr | Pt | SiO₂ | Cr₂O₃ | molar ratio | (° C.) | (μm) | (%) |
| Ex. 1 | 67.6 | 9.6 | 19.3 | 2.5 | 1.0 | 8.1 | 66.8 | 10.4 | 19.1 | 2.5 | 1.2 | 0.5 | 1050 | 2.7 | 98.0 |
| Ex. 2 | 67.2 | 9.6 | 19.2 | 2.5 | 1.5 | 8.6 | 66.4 | 10.4 | 19.0 | 2.5 | 1.7 | 0.7 | 1050 | 2.6 | 97.7 |
| Ex. 3 | 66.5 | 9.5 | 19.0 | 2.5 | 2.5 | 9.7 | 65.7 | 10.4 | 18.8 | 2.5 | 2.6 | 1.1 | 1050 | 2.4 | 97.4 |
| Ex. 4 | 64.8 | 9.2 | 18.5 | 2.5 | 5.0 | 12.3 | 64.0 | 10.1 | 18.3 | 2.5 | 5.1 | 2.1 | 1050 | 2.3 | 97.0 |
| Ex. 5 | 67.2 | 9.6 | 19.2 | 1.5 | 2.5 | 9.8 | 66.4 | 10.4 | 19.0 | 1.5 | 2.7 | 1.8 | 1050 | 2.1 | 97.2 |
| Ex. 6 | 59.9 | 8.5 | 17.1 | 12.0 | 2.5 | 9.3 | 59.3 | 9.3 | 16.9 | 11.9 | 2.6 | 0.2 | 1050 | 2.7 | 98.4 |
| Ex. 7 | 59.9 | 8.5 | 17.1 | 2.5 | 12.0 | 19.2 | 59.2 | 9.4 | 16.9 | 2.5 | 12.0 | 4.9 | 1050 | 2.9 | 96.5 |
| Comp. Ex. 1 | 68.3 | 9.7 | 19.5 | 2.5 | 0.0 | 6.9 | 67.5 | 10.5 | 19.3 | 2.5 | 0.2 | 0.1 | 1050 | 3.3 | 96.4 |
| Comp. Ex. 2 | 67.9 | 9.7 | 19.4 | 2.5 | 0.5 | 7.5 | 67.1 | 10.5 | 19.2 | 2.5 | 0.7 | 0.3 | 1050 | 3.2 | 98.4 |
| Ref. Ex. 1 | 67.2 | 9.6 | 19.2 | 1.5 | 2.5 | 9.8 | 66.4 | 10.5 | 19.0 | 1.5 | 2.6 | 1.8 | 1150 | 3.5 | 99.4 |
| Ref. Ex. 2 | 69.0 | 9.8 | 19.7 | 1.5 | 0.0 | 7.0 | 68.2 | 10.6 | 19.5 | 1.5 | 0.2 | 0.1 | 1150 | 4.0 | 99.4 |

1. A process for producing a sputtering target material comprising a cobalt/chromiuin/platinum matrix phase and an oxide phase that comprises two or more metal oxides including at least chromium oxide wherein the oxide phase is in the form of particles, which process comprises sintering material powder to form the sputtering target material wherein the material powder contains chromium oxide at not less than 1.0 mol % based on the material powder.

2. The process according to claim 1, wherein the particles forming the oxide phase have an average particle diameter of not more than 3 μm.

3. The process according to claim 1, wherein the oxide phase comprises chromium oxide and at least one metal oxide selected from the group consisting of silicon oxide, titanium oxide, tantalum oxide, aluminum oxide, magnesium oxide, calcium oxide, zirconium oxide, boron oxide, manganese oxide, samarium oxide, hafnium oxide and gadolinium oxide.

4. The process according to claim 1, wherein the chromium oxide is at least one selected from the group consisting of Cr₂O₃, CrO, CrO₂, Cr₂O₅ and CrO₃.

5. The process according to claim 1, wherein the oxide phase comprises chromium oxide and a Si-containing oxide, and the sputtering target material contains chromium oxide at 1.2 to 12.0 mol % and the Si-containing oxide at 1.5 to 11.9 mol % based on the sputtering target material.

6. The process according to claim 1, wherein the material powder is sintered by electric current sintering at a temperature of not more than 1100° C.

7. A sputtering target material comprising a cobalt/chromium/platinum matrix phase and an oxide phase that comprises two or more metal oxides including at least chromium oxide wherein the oxide phase is in the form of particles having an average particle diameter of not more than 3 μm and comprises chromium oxide and a Si-containing oxide, the sputtering target material containing chromium oxide at 1.2 to 12.0 mol % and the Si-containing oxide at 1.5 to 11.9 mol % based on the sputtering target material.

8. The process according to claim 2, wherein the oxide phase comprises chromium oxide and at least one metal oxide selected from the group consisting of silicon oxide, titanium oxide, tantalum oxide, aluminum oxide, magnesium oxide, calcium oxide, zirconium oxide, boron oxide, manganese oxide, samarium oxide, hafnium oxide and gadolinium oxide.

9. The process according to claim 2, wherein the chromium oxide is at least one selected from the group consisting of Cr₂O₃, CrO, CrO₂, Cr₂O₅ and CrO₃.

10. The process according to claim 3, wherein the chromium oxide is at least one selected from the group consisting of Cr₂O₃, CrO, CrO₂, Cr₂O₅ and CrO₃.

11. The process according to claim 2, wherein the oxide phase comprises chromium oxide and a Si-containing oxide, and the sputtering target material contains chromium oxide at 1.2 to 12.0 mol % and the Si-containing oxide at 1.5 to 11.9 mol % based on the sputtering target material.

12. The process according to claim 3, wherein the oxide phase comprises chromium oxide and a Si-containing oxide, and the sputtering target material contains chromium oxide at 1.2 to 12.0 mol % and the Si-containing oxide at 1.5 to 11.9 mol % based on the sputtering target material.

13. The process according to claim 4, wherein the oxide phase comprises chromium oxide and a Si-containing oxide, and the sputtering target material contains chromium oxide at 1.2 to 12.0 mol % and the Si-containing oxide at 1.5 to 11.9 mol % based on the sputtering target material.

14. The process according to claim 2, wherein the material powder is sintered by electric current sintering at a temperature of not more than 1100° C.

15. The process according to claim 3, wherein the material powder is sintered by electric current sintering at a temperature of not more than 1100° C.

16. The process according to claim 4, wherein the material powder is sintered by electric current sintering at a temperature of not more than 1100° C.

17. The process according to claim 5, wherein the material powder is sintered by electric current sintering at a temperature of not more than 1100° C.
